(19) United States
(12) Patent Application Publication
(10) Pub. No.: US 2009/0002949 A1
(43) Pub. Date: Jan. 1, 2009

(54) HEAT TRANSFER FOR ELECTRONIC COMPONENT VIA AN ELECTROMAGNETIC INTERFERENCE (EMI) SHIELD HAVING SHIELD DEFORMATION

(75) Inventors: Ivan Pawlenko, Holland, PA (US); Larry Samson, Langhorne, PA (US)

Correspondence Address: MENDELSOHN & ASSOCIATES, P.C., 1500 JOHN F. KENNEDY BLVD., SUITE 405, PHILADELPHIA, PA, 19102, US

(73) Assignee: LUCENT TECHNOLOGIES INC., Murray Hill, NJ (US)

(21) Appl. No.: 11/770,846

(22) Filed: Jun. 29, 2007

(51) Int. Cl. H05K 7/20; H05K 9/00

(52) U.S. Cl. 361/707; 361/818

(57) ABSTRACT

In one embodiment, an apparatus having an electromagnetic interference (EMI) shield for an electronic component. The EMI shield and the electronic component are adapted to be assembled onto a circuit board. The EMI shield provides EMI shielding for the electronic component. The EMI shield includes a thermally conductive material, such as a metal. The EMI shield is deformed, e.g., with a dimple or a tab, to form a contacting portion to contact the electronic component. After the assembly of the EMI shield and the electronic component onto the circuit board, the contacting portion of the EMI shield contacts the electronic component, thereby allowing conductive transfer of thermal energy between the electronic component and the EMI shield and enhanced heat dissipation for the electronic component.

### BACKGROUND OF THE INVENTION

1. Field of the Invention

The present invention relates to heat-dissipation enhancement in circuit packs having components with electromagnetic interference (EMI) shielding.

2. Description of the Related Art

A circuit pack typically comprises a plurality of variously interconnected and physically proximate electronic components that are soldered to a base circuit board. As used herein, “circuit pack” refers to any configuration of one or more electronic components connected on a common substrate. These electronic components may include integrated circuits, analog devices, digital devices, and radio-frequency (RF) components. One or more electronic components may require an electromagnetic interference (EMI) shield, also referred to as an RF shield or a can. An EMI shield is useful for reducing electromagnetic interference (i) caused by the shielded component and/or (ii) that can affect the shielded component. Thus, an EMI shield can be used to protect other components from EMI generated by the shielded component, and an EMI shield can be used to protect the shielded component from externally-generated EMI. A simple EMI shield is typically made in the shape of an open-bottomed metal enclosure placed over the shielded component and attached to the base circuit board.

As would be appreciated by one of ordinary skill in the art, there are many ways to form an EMI shield enclosure. For example, the EMI shield can be a unitary piece attached to a circuit board, as disclosed in U.S. Pat. No. 5,530,202 to Dais et al., incorporated herein by reference in its entirety. The EMI shield can also be formed by attaching a lid to a walled enclosure that was previously attached to a circuit board, as disclosed in U.S. Pat. Nos. 7,095,624 B2 to Daoud et al. and 7,113,410 B2 to Pawlenko et al., incorporated herein by reference in their entirety.

The shielded component may get hot in operation and consequently may benefit from heat-dissipation enhancement to prevent overheating of the shielded component. The phrase “heat-dissipation enhancement,” as used herein, unless otherwise indicated, describes any means whose use increases, or is intended to increase, the heat-loss, or cooling, rate of a component. One way to cool the shielded component is with an airflow provided by a fan associated with the circuit pack. Circuit packs typically use one or more fans to provide cooling air for circuit pack components. In order for the cooling air to reach the shielded component, the EMI shield may be perforated. EMI-shield perforations whose diameters are at least about an order of magnitude smaller than the wavelengths of the EMI of concern generally do not significantly degrade the shielding performance of the EMI shield.

FIG. 1 shows prior-art EMI shield 102 on a partial circuit board 101. EMI shield 102 is perforated to allow cooling air to reach a shielded component (not shown). Another way to provide thermal dissipation for the shielded component is to interpose a metal coil spring connected between the shielded component and the EMI shield. The metal spring conducts heat from the shielded component to the surface of the EMI shield from where it may be more easily dissipated. The spring is useful for maintaining contact between the shielded component and the EMI shield while allowing for physical-dimension variations due to (i) component dimensional tolerances and/or (ii) temperature-related expansion and/or contraction.

FIG. 2 shows a cutaway view of exemplary prior-art heat-dissipating EMI-shielding box 200. Box 200 comprises EMI shield 201, which includes top section 202. EMI shield 201 has perforations to allow for easier circulation of air within it. Top section 202 can be a lid that is attached after the rest of EMI shield 201 is mounted onto a circuit board (not shown), or top section 202 can be an integral part of EMI shield 201, i.e., formed together with the rest of EMI shield 201 prior to mounting on a circuit board. Box 200 further comprises copper coil spring 203, which is attached to copper slug 204. Copper slug 204 is attached to top section 202, for example, with a screw (not shown). When box 200 is in place in a circuit pack, copper coil spring 203 is in contact with a shielded component (not shown) and is therefore compressed to an extent determined by, among other factors, the length of copper coil spring 203, and the heights of the shielded component and of EMI shield 201. Heat can therefore be conductively dissipated from the shielded component via copper coil spring 203, copper slug 204, and EMI shield 201.

As the operating frequencies of components keep increasing, their operating temperatures increase and novel means of heat dissipation for EMI-shielded components may be useful.

### SUMMARY OF THE INVENTION

In one embodiment, the invention can be an apparatus comprising an electromagnetic interference (EMI) shield for an electronic component, wherein the EMI shield and the electronic component are adapted to be assembled onto a circuit board. The EMI shield is adapted to provide EMI shielding for the electronic component. The EMI shield comprises a thermally conductive material, such that, after the assembly of the EMI shield and the electronic component onto the circuit board, a portion of the EMI shield contacts the electronic component, thereby allowing conductive transfer of thermal energy between the electronic component and the EMI shield.

In another embodiment, the invention can be a method for allowing the conduction of thermal energy from an electronic component, the method comprising assembling an electronic component onto a circuit board, and assembling an EMI shield onto the circuit board. The EMI shield is adapted to provide EMI shielding for the electronic component. The EMI shield comprises a thermally conductive material, such that, after the assembly of the EMI shield and the electronic component onto the circuit board, a portion of the EMI shield contacts the electronic component, thereby allowing conductive transfer of thermal energy between the electronic component and the EMI shield.

In yet another embodiment, the invention can be a method for operating an apparatus comprising an electronic component and an electromagnetic interference (EMI) shield. The method comprises providing shielding for the electronic component by the EMI shield, wherein the EMI shield comprises a thermally conductive material, and a portion of the EMI shield contacts the electronic component. The method further comprises conducting thermal energy between the electronic component and the EMI shield.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows an exemplary prior-art EMI shield on a circuit board.

FIG. 2. shows a cutaway perspective view of an exemplary prior-art EMI shield with a copper coil spring.

FIG. 3 shows a cross-sectional view of part of an exemplary circuit pack in accordance with an embodiment of the current invention.

FIG. 4 shows a cutaway perspective view of an exemplary circuit pack in accordance with another embodiment of the current invention.

FIG. 5. shows a cutaway perspective view of an exemplary circuit pack in accordance with yet another embodiment of the current invention.

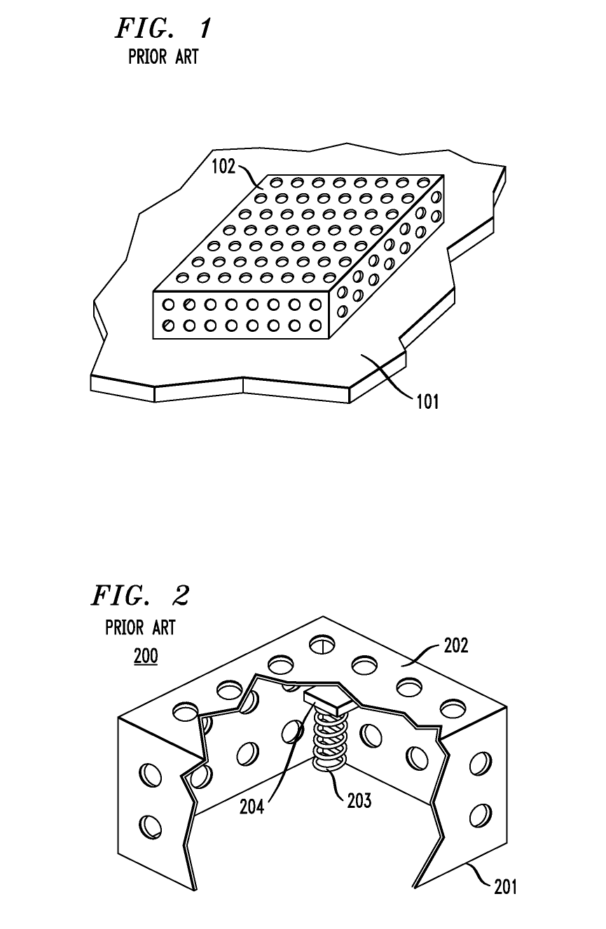

### DETAILED DESCRIPTION

Heat-dissipation enhancement may be provided for an EMI-shielded component by deforming the EMI shield so that a portion of the top surface of the EMI shield comes into contact with the shielded component. Prior to the deformation of the top surface of the EMI shield, the top surface of the EMI shield is substantially planar. One way to achieve this heat-dissipation enhancement is to press the top of EMI shield so as to form one or more craters or dimples whose bottom sections will come into contact with the top of the shielded component. Another way to achieve this is by cutting and bending the EMI shield to form one or more tabs which will come into contact with the top of the shielded component.

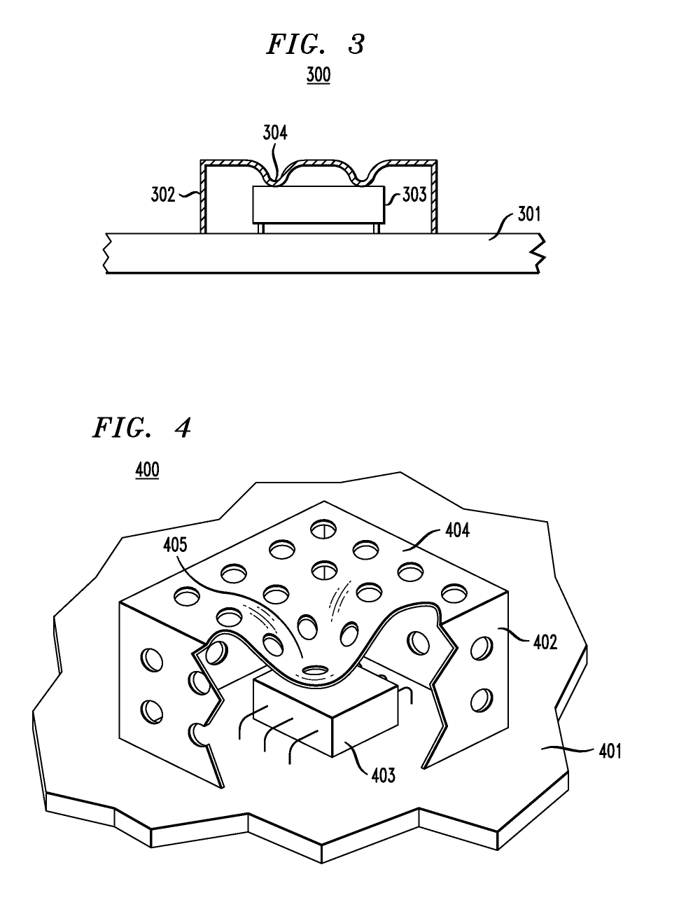

FIG. 3 shows a cross-sectional view of part of exemplary circuit pack 300, in accordance with an embodiment of the current invention. Circuit pack 300 comprises circuit board 301, EMI shield 302, and shielded component 303. Component 303 may require EMI shielding from externally-generated EMI, or component 303 may require EMI shielding to protect other components from EMI that component 303 generates, or component 303 may require EMI shielding for both purposes. Component 303 can, for example, be a transformer, a coil, an inductor, an integrated circuit, an amplifier, or a transistor. EMI shield 302 may enclose additional components requiring EMI shielding (not shown), as well as additional components that do not require EMI shielding (not shown).

EMI shield 302 is made of a material, such as a metal, that is thermally conductive, is malleable, and provides EMI shielding. EMI shield 302 may be attached to circuit board 301 by soldering (e.g. using solder reflow), clasping, gluing, welding, adhering, bolting, screwing, or by any other suitable attachment means. EMI shield 302 may be of virtually any shape that substantially creates an enclosure when placed over shielded component 303. A typical shape is substantially an open-bottomed rectangular box. EMI shield 302 may be perforated so as to allow cooling air to flow through the space inside EMI shield 302 and cool component 303. EMI shield 302 may also have additional perforations for other purposes and such perforations may be smaller or larger than the air-flow perforations and may even degrade the effectiveness of the EMI shielding.

The top section of EMI shield 302 is dimpled and includes dimples such as dimple 304. The dimples are formed, for example, by a metal press or punch. As would be appreciated by a person of ordinary skill in the art, the creation of a dimple by pressing causes the material in the dimple to become thinner. This thinning makes the dimples more malleable, which allows them to more easily deform and conform to the contours of the top of shielded component 303. EMI shield 302 may have many relatively small dimples or one relatively large dimple. If EMI shield 302 is perforated and has many small dimples, then some care may need to be exercised to avoid having all the dimple locations coincide with perforations, as that could prevent functional dimples from forming. For example, if the means for forming the dimples is calibrated for a perforation-free surface, and if the perforations and dimples are all aligned, then the dimple-forming means may fail to make dimples in EMI shield 302 that would contact component 303. However, if EMI shield 302 is perforated and uses one or more relatively large dimples, then the effect of the perforations on the utility of the dimple is likely to be minimal. The dimples may have rounded bottoms, or may have somewhat flattened, or otherwise shaped, bottoms which may increase the contact area with the top of component 303, thereby enhancing thermal dissipation for component 303.

In one embodiment, the height of EMI shield 302 is such that (a) EMI shield 302 can be attached, on top of component 303, to circuit board 301 without materially damaging EMI shield 302, component 303, or circuit board 301, and (b) when EMI shield 302 is so attached, at least one dimple 304 comes into contact with the top of component 303. Additional dimples may also come into contact with the top of component 303. Both dimple 304 and other parts of EMI shield 302 may undergo some deformation during such an attachment from the forces acting on them. The extent of the deformation depends on factors such as the dimensions of the elements and their compositions. If EMI shield 302 is too tall, then dimple 304 will not come into contact with component 303, and if EMI shield 302 is too short, then circuit board 301, component 303, and/or EMI shield 302 may be materially damaged by an attachment attempt. Material damage includes visible breaking and cracking of a component, and any damage that renders a component not operable as intended.

FIG. 4 shows a cutaway perspective view of exemplary circuit pack 400 in accordance with an embodiment of the current invention that is similar to circuit pack 300 in FIG. 3. Circuit pack 400 comprises circuit board 401, EMI shield 402, and component 403. EMI shield 402 includes top section 404 and depression 405, which is substantially a large dimple or crater. EMI shield 402 is perforated to enhance air circulation within EMI shield 402. The bottom section of depression 405 is in contact with the top of component 403, thereby enhancing the dissipation of heat from component 403. Top section 404 may be an integral part of EMI shield 402, i.e., part of the same uncut form used to generate the rest of EMI shield 402. Alternatively, top section 404 may be a lid that is attached to the rest of EMI shield 402 at an appropriate stage of the assembly of circuit pack 400. An example of an appropriate stage for the attachment of lid-form top section 404 would be after the attachment of component 403 and the rest of EMI shield 402 to circuit board 401 and after the formation of depression 405 in top section 404.

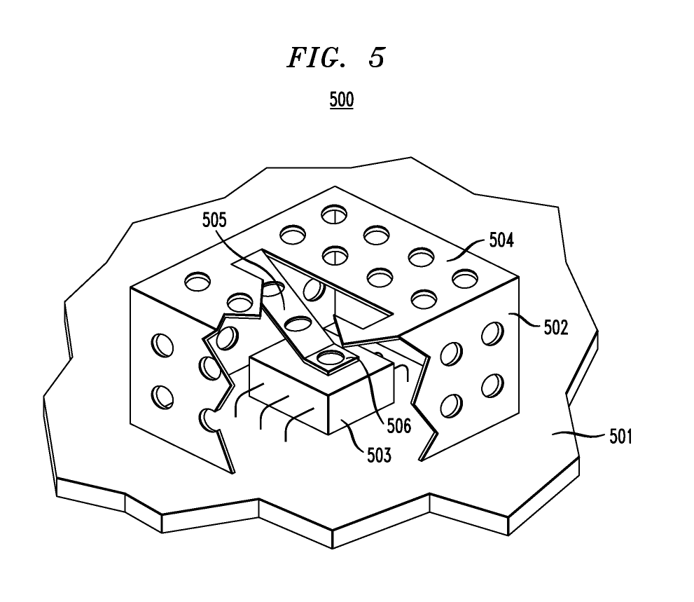

FIG. 5 shows a cutaway perspective view of exemplary circuit pack 500 in accordance with another embodiment of the current invention. Circuit pack 500 comprises circuit board 501, EMI shield 502, and component 503. EMI shield 502 is perforated. EMI shield 502 includes top section 504. Top section 504 may be an integral part of EMI shield 502, i.e., part of the same uncut form used to generate the rest of EMI shield 502. Alternatively, top section 504 may be a lid that is attached to the rest of EMI shield 502 at an appropriate stage of the assembly of circuit pack, wherein top section 504 is deformed prior to attachment to the rest of EMI shield 502.

Top section 504 comprises tab 505. Tab 505 is formed from top section 504 so as to form a thermally conductive path from component 503 to EMI shield 502. Tab 505 may be formed, for example, by cutting in top section 504 all sides but one of any polygonal shape and then pressing down on the polygon so that tab 505 is bent down at the uncut side of the polygon. The bending should be such that when circuit pack 500 is completely assembled, tab 505 is in contact with component 503. Tab 505 may be additionally bent or deformed to form pad 506 to increase the area of tab 505 in contact with component 503, thereby enhancing the dissipation of heat from component 503.

In one alternative embodiment, multiple tabs are cut out of top section 504. In one alternative embodiment, one or more tabs are cut out of other sections of EMI shield 502 and form one or more thermally conductive paths from component 503 to EMI shield 502.

Although embodiments of the invention have been described as having an EMI shield perforated, alternative embodiments have an EMI shield that does not have perforations. Although embodiments of the invention have been described as having a cut-out portion of the EMI shield in contact with the top of a shielded component, alternative embodiments have the cut-out portion of the EMI shield in contact with other surfaces of the shielded component, as may be appropriate and as would be appreciated by one of ordinary skill in the art.

Although embodiments of the invention have been described as having the top portion of an EMI shield deformed to contact a shielded component, alternative embodiments have other portions of the EMI shield, such as one or more side portions, deformed to contact the shielded component. Although embodiments of the invention have been described as having an EMI shield deformed to create dimples or tabs, alternative embodiments have the EMI shield formed already with dimples or tabs. Although embodiments of the invention have been described as having an EMI shield deformed prior to completely assembling a corresponding circuit pack, alternative embodiments have the EMI shield deformed after the EMI shield and shielded component are assembled.

In one alternative embodiment, a deformed EMI shield and a shielded component are combined into an integrated shielded component wherein the integrated shielded component is attached as a single unit as part of a circuit pack. Such integration may provide enhanced EMI shielding as it allows for shielding on the bottom of the component.

It will be understood that various changes in the details, materials, and arrangements of the parts which have been described and illustrated in order to explain the nature of this invention may be made by those skilled in the art without departing from the scope of the invention as expressed in the following claims.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Unless explicitly stated otherwise, each numerical value and range should be interpreted as being approximate as if the word “about” or “approximately” preceded the value of the value or range. As used in this application, unless otherwise explicitly indicated, the term “connected” is intended to cover both direct and indirect connections between elements.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures. Furthermore, the use of particular terms and phrases herein is for the purpose of facilitating the description of the embodiments presented and should not be regarded as limiting.

References in descriptions of alternative embodiments to particular figures or previously-described embodiments do not limit the alternatives to those particular shown or previously-described embodiments. Alternative embodiments described can generally be combined with any one or more of the other alternative embodiments shown or described.

Although the steps in the following method claims are recited in a particular sequence with corresponding labeling, unless the claim recitations otherwise imply a particular sequence for implementing some or all of those steps, those steps are not necessarily intended to be limited to being implemented in that particular sequence.

We claim:

1. An apparatus comprising an electromagnetic interference (EMI) shield for an electronic component, wherein:
the EMI shield and the electronic component are adapted to be assembled onto a circuit board;
the EMI shield is adapted to provide EMI shielding for the electronic component; and
the EMI shield comprises a thermally conductive material, such that, after the assembly of the EMI shield and the electronic component onto the circuit board, a portion of the EMI shield contacts the electronic component, thereby allowing conductive transfer of thermal energy between the electronic component and the EMI shield.

2. The apparatus of claim 1, wherein the EMI shield is perforated.

3. The apparatus of claim 1, wherein the apparatus further comprises the electronic component.

4. The apparatus of claim 3, wherein the apparatus further comprises a circuit pack, wherein the circuit pack comprises the EMI shield, the electronic component, and the circuit board.

5. The apparatus of claim 1, wherein a deformation of the EMI shield comprises the contacting portion of the EMI shield.

6. The apparatus of claim 5, wherein the deformation comprises at least one dimple.

7. The apparatus of claim 6, wherein the deformation comprises exactly one dimple.

8. The apparatus of claim 5, wherein the deformation comprises one or more tabs bent from the EMI shield.

9. The apparatus of claim 8, wherein for at least one of the one or more tabs, one end of the tab remains attached to the EMI shield and the tab is bent from the EMI shield at the attachment location such that another end of the tab forms the contacting portion.

10. The apparatus of claim 9, wherein the tab is bent such that the contacting portion has greater surface area for contact with the electronic component.

11. The apparatus of claim 8, wherein at least one of the one or more tabs is cut out of a top surface of the EMI shield.

12. The apparatus of claim 5, wherein, prior to the deforming of the EMI shield, the top surface of the EMI shield is substantially planar.

13. The apparatus of claim 1, wherein:
prior to the assembly onto the circuit board, the EMI shield comprises a top section and a separate enclosure section; and
the top section is adapted to be attached to the separate enclosure section.

14. The apparatus of claim 13, wherein the top section comprises the contacting portion of the EMI shield.

15. A method for allowing the conduction of thermal energy from an electronic component, the method comprising:
assembling an electronic component onto a circuit board; and
assembling an EMI shield onto the circuit board, wherein:
the EMI shield is adapted to provide EMI shielding for the electronic component; and
the EMI shield comprises a thermally conductive material, such that, after the assembly of the EMI shield and the electronic component onto the circuit board, a portion of the EMI shield contacts the electronic component, thereby allowing conductive transfer of thermal energy between the electronic component and the EMI shield.

16. The method of claim 15, further comprising deforming a top surface of the EMI shield to form the contacting portion of the EMI shield.

17. The method of claim 16, wherein, prior to the deforming of the top surface of the EMI shield, the top surface of the EMI shield is substantially planar.

18. The method of claim 16, wherein the deforming comprises pressing on the top surface of the EMI shield to form one more dimples, wherein at least one of the one or more dimples comprises the contacting portion of the EMI shield.

19. The method of claim 17, wherein the deforming comprises bending one or more tabs from the top surface of the EMI shield, wherein at least one of the one or more tabs comprises the contacting portion of the EMI shield.

20. A method for operating an apparatus comprising an electronic component and an electromagnetic interference (EMI) shield, the method comprising:
providing shielding for the electronic component by the EMI shield, wherein:
the EMI shield comprises a thermally conductive material; and
a portion of the EMI shield contacts the electronic component; and
conducting thermal energy between the electronic component and the EMI shield.
